(19) United States
(12) Patent Application Publication
(10) Pub. No.: US 2014/0284794 A1
(43) Pub. Date: Sep. 25, 2014

(54) TIN-BASED SOLDER BALL AND SEMICONDUCTOR PACKAGE INCLUDING THE SAME

(71) Applicant: MK ELECTRON CO., LTD., Yongin-si, Gyeonggi-do (KR)

(72) Inventors: Jae Hong Lee, Seoul (KR); II Ho Kim, Yongin-si (KR); Sung Jae Hong, Yongin-si (KR); Jeong Tak Moon, Suwon-si (KR)

(73) Assignee: MK ELECTRON CO., LTD., Yongin-si, Gyeonggi-do (KR)

(21) Appl. No.: 13/818,034

(22) PCT Filed: Nov. 7, 2012
(86) PCT No.: PCT/KR2012/009317

§ 371 Date: Feb. 20, 2013

(51) Int. Cl. B23K 35/26; H01L 23/00

(52) U.S. Cl. CPC B23K 35/262; H01L 24/13; H01L 2224/13639; H01L 2924/014; H01L 2224/13647
USPC 257/738; 420/561

(57) ABSTRACT

A tin (Sn)-based solder ball having appropriate characteristics for electronic products and a semiconductor package including the same are provided. The tin-based solder ball includes about 0.3 to 3.0 wt. % silver (Ag), about 0.4 to 0.8 wt. % copper (Cu), about 0.01 to 0.09 wt. % nickel (Ni), about 0.1% to 0.5 wt. % bismuth (Bi), and balance of tin (Sn) and unavoidable impurities.

### CROSS REFERENCE TO RELATED APPLICATION

This application claims the benefit of International Application No. PCT/KR2012/009317, filed Nov. 7, 2012, which is incorporated by reference as if fully set forth.

### TECHNICAL FIELD

The present invention relates to a tin(Sn)-based solder ball, and more particularly, to a tin (Sn)-based solder ball and a semiconductor package including the same.

### BACKGROUND ART

With the trend toward highly efficient, downscaled electronic devices, miniaturizing packages during an assembly process of the electronic devices is required. Thus, solder balls are being used instead of conventional lead frames to attain miniaturization of the packages. The solder balls may serve to bond a substrate with a package and transmit signals from chips of the package to a substrate.

To reduce environmental pollution, lead(Pb)-free solder balls have been proposed. For example, although solder balls formed of a ternary lead-free solder alloy (e.g., tin(Sn)-silver(Ag)-copper(Cu)) have been suggested, the solder balls may have low thermal cyclic characteristics and be vulnerable to oxidation and solder has low spreading characteristics and low wettability. Thus, the suggested solder balls have poor workability and weak resistance to mechanical impacts, so the solder balls are inappropriate for portable electronic products. Accordingly, there have been attempts at improving characteristics of solder balls by further adding another element to Sn—Ag—Cu, but the characteristics of the solder balls largely vary according to the kind and content of the element.

### Related Art Document

1. Registered Japanese Patent No. 3602529 (Oct. 1, 2004)

2. Registered Japanese Patent No. 4392020 (Oct. 16, 2009)

3. Published Japanese Patent No. 2004-188453 (Jul. 8, 2004)

### DETAILED DESCRIPTION OF THE INVENTION

### Technical Problem

The present invention provides a tin (Sn)-based solder ball formed of an alloy, which has characteristics required for solder balls appropriate for electronic products.

The present invention also provides a semiconductor package including the Sn-based solder ball.

### Technical Solution

According to an aspect of the present invention, there is provided a tin-based solder ball including about 0.3 to 3.0 wt. % silver (Ag), about 0.4 to 0.8 wt. % copper (Cu), about 0.01 to 0.09 wt. % nickel (Ni), about 0.1% to 0.5 wt. % bismuth (Bi), and balance of tin (Sn) and unavoidable impurities.

Bismuth may be contained at a content of about 0.1 to 0.3 wt. %. Bismuth may be contained at a content of about 0.2(±0.02) wt. %.

Nickel may be contained at a content of about 0.05(±0.01) wt. %.

Silver may be contained at a content of about 2.5 wt. %, copper may be contained at a content of about 0.8 wt. %, nickel may be contained at a content of about 0.05 wt. %, and bismuth may be contained at a content of about 0.2 wt. %.

According to another aspect of the present invention, there is provided a tin-based solder ball including silver, copper, nickel, bismuth, and balance of tin and unavoidable impurities. Phosphorus (P) is removed from the tin-based solder ball.

According to another aspect of the present invention, there is provided a semiconductor package including a tin (Sn)-based solder ball. The tin-based solder ball includes about 0.3 to 3.0 wt. % silver, about 0.4 to 0.8 wt. % copper, about 0.01 to 0.09 wt. % nickel, about 0.1% to 0.5 wt. % bismuth, and balance of tin and unavoidable impurities.

### Advantageous Effects

The present invention provides a tin-based solder ball containing silver, copper, nickel, and bismuth. The tin-based solder ball can have good thermal cyclic characteristics and high drop durability and endurance according to the content range of each of added elements.

### BRIEF DESCRIPTION OF THE DRAWINGS

FIG. 1 is a schematic view of a tin (Sn)-based solder ball according to an embodiment of the present invention; and

FIGS. 2 through 4 are schematic views of semiconductor packages including Sn-based solder balls according to exemplary embodiments of the present invention.

### MODE OF THE INVENTION

The present invention is described more fully hereinafter with reference to the accompanying drawings, in which embodiments of the invention are shown. In the drawings, the same reference numerals are used to denote the same elements, and repeated description thereof is omitted. This invention may, however, be embodied in many different forms and should not be construed as limited to the embodiments set forth herein. Rather, these embodiments are provided so that this disclosure will be thorough and complete, and will fully convey the scope of the invention to those skilled in the art. As used herein, the term “and/or” includes any and all combinations of one or more of the associated listed items. Like numbers refer to like elements throughout. Furthermore, since various elements and regions are schematically illustrated in drawings, the present invention is not limited by relative sizes or intervals of the drawings. In embodiments of the present invention, a weight proportion (wt. %) refers to the weight of the corresponding element, which is converted in terms of a percentage, out of the weight of the entire alloy.

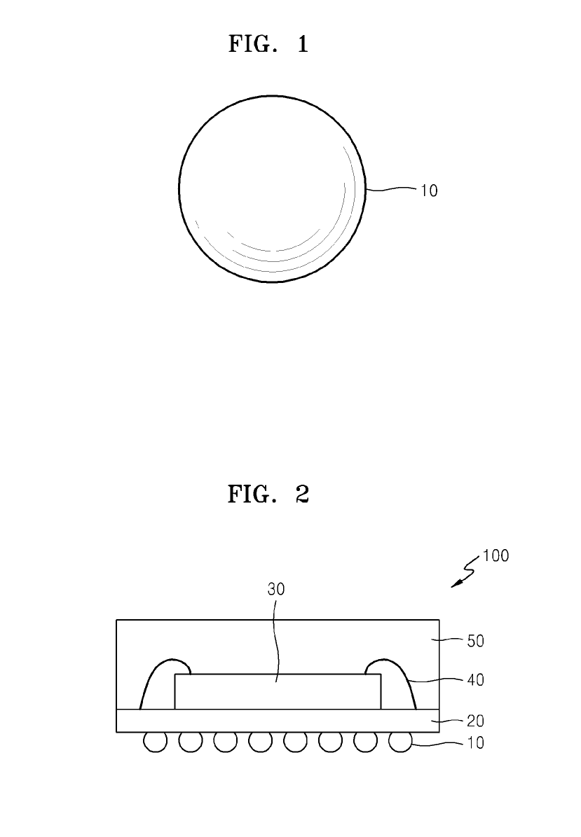

FIG. 1 illustrates a tin (Sn)-based solder ball 10 according to an exemplary embodiment of the present invention.

Referring to FIG. 1, the tin-based solder ball 10 may have a spherical shape. However, the tin-based solder ball 10 is not limited to the spherical shape and may have a cylindrical shape or a polygonal shape in the present invention.

The tin-based solder ball 10 may be formed of a tin-based alloy. For example, the tin-based solder ball 10 may include silver (Ag), copper (Cu), nickel (Ni), and bismuth (Bi) and balance of tin and other unavoidable impurities. For example, the tin-based solder ball 10 may be formed 0.3 to 3.0 wt. % silver; 0.4 to 0.8 wt. % copper; 0.01 to 0.09 wt. % nickel; 0.1 to 0.5 wt. % bismuth, and balance of tin and other unavoidable impurities. For instance, the tin-based solder ball may include tin and unavoidable impurities having a content of about 95.61 to 98.99 wt. %.

The tin-based solder ball 10 may contain bismuth at a content of about 0.1 to 0.3 wt. %. The tin-based solder ball 10 may contain bismuth at a content of about 0.2(±0.02) wt. %. The tin-based solder ball 10 may contain nickel at a content of about 0.05(±0.01) wt. %. Also, phosphorus (P) may be removed from the tin-based solder ball 10.That is, the tin-based solder 10 may contain phosphorus within the content range of the unavoidable impurities. For example, the tin-based solder ball 10 may contain phosphorus at a content of less than about 0.003 wt. % (or 30 ppm), for example, at a content of less than about 0.001 wt. % (or 10 ppm).

The tin-based solder ball 10 according to the present invention may be formed based on tin. Since the use of lead (Pb) applied to conventional solder balls is prohibited by environmental protection regulations, attempts at adopting tin-based solder balls instead of lead-based solder balls have increased. Tin is an element in Group 14 and Period 5 of the periodic table and has a standard atomic weight of about 118.7 g/mol and a melting point of about 231.93° C. In comparison, lead is an element in Group 14 and Period 6 of the periodic table and has a standard atomic weight of about 207.2 g/mol and a melting point of about 327.5° C. Thus, tin has similar physical properties to those of lead. Tin has good malleability, ductility, corrosion resistance, and castibility. However, to meet requirements for solder balls, such as thermal cyclic characteristics, drop durability, or wettability, solder balls may be formed of an alloy of tin and other metals rather than only tin. To meet the above-described needs, the present invention provides a technique of forming solder balls using a tin-based alloy formed by alloying tin with silver, copper, nickel, and bismuth.

The tin-based solder ball 10 according to the present invention may contain silver, which may reduce electrical resistances of solder balls, increase a diffusion rate of solder balls into bonding portions, and increase corrosion resistance. When silver is contained in the solder ball 10 at a content of less than 0.1 wt. %, it may be difficult to ensure a sufficient electrical conductivity and thermal conductivity of the solder ball 10 and difficult to increase the diffusion rate of the solder ball 10. Also, when silver is contained in the solder ball at a content of more than about 5 wt. %, it may be difficult to control a melting temperature of the solder ball 10 for a reflow process. Thus, silver may be contained in the solder ball 10 at a content of about 0.1 to 5 wt. %, particularly, a content of about 0.3 to 3 wt. %.

The tin-based solder ball 10 according to the present invention may contain copper, which may affect the tensile strength of the solder ball 10. When copper is contained in the solder ball 10 at a content of less than about 0.1 wt. %, it may be difficult to increase the tensile strength of the solder ball 10 as desired. Also, when copper is contained in the solder ball 10 at a content of more than about 1 wt. %, solder may be hardened so that the solder ball may be easily damaged, thereby reducing processibility. Thus, in the present embodiment, copper may be contained in the solder ball 10 at a content of about 0.1 to 1 wt. %, particularly, a content of about 0.4 to 0.8 wt. %. In particular, as the content of copper in the solder ball 10 increases (e.g., when copper is contained in the solder ball 10 at a content of about 0.6 to 0.8 wt. %), generation of Cu3Sn, which is a weak inter-metallic compound, may be suppressed.

The tin-based solder ball 10 according to the present invention may contain nickel, which may improve flowability during a melting process and enhance thermal cyclic characteristics and drop durability. For example, the tin-based solder ball 10 may contain nickel at a content of about 0.01 to 0.09 wt. %. When nickel is contained in the solder ball 10 at a content of less than about 0.01 wt. %, effects of nickel may not be properly produced, and when nickel is contained in the solder ball 10 at a content of more than about 0.09 wt. %, a melting point of the solder ball 10 may rise, wettability may be degraded, and flowability may be reduced during a melting process.

The tin-based solder ball 10 according to the present invention may contain bismuth, which is an element in Group 15 and Period 6 of the periodic table. Bismuth has a standard atomic weight of about 208.98 g/mol and a melting point of about 271.5° C. Bismuth may reduce the melting point of the solder ball 10, improve wettability to increase a mechanical strength, and increase shear stress of the solder ball 10. When the solder ball 10 contains bismuth at a content of about 0.1 wt. % or more, Ag3Sn, which is an inter-metallic compound, may be uniformly distributed, and crystal grains may be miniaturized to improve thermal cyclic characteristics. However, when the solder ball 10 contains bismuth at a content of more than 0.5 wt. %, a Bi-rich precipitate phase may be precipitated to improve brittleness of the solder ball 10.

The tin-based solder ball 10 according to the present invention may not contain phosphorus or contain phosphorus within the content range of unavoidable impurities, for example, at a content of less than about 0.003 wt. % (or 30 ppm), particularly, at a content of less than 0.001 wt. % (or 10 ppm). Phosphorus may form a phosphorus oxide layer on the surface of the solder ball 10 and degrade wettability.

Hereinafter, variations in the characteristics of the tin-based solder ball 10 according to the content range of each of elements of the tin-based solder ball 10 according to the present invention will be examined based on experimental data. To analyze the variations in the characteristics of the tin-based solder ball 10, experiments were made on the thermal cyclic characteristics, drop durability, and wettability of the tin-based solder ball 10.

Solder balls used for the experiments had a size of about 300 μm. A substrate used for experiments on the thermal cyclic characteristics and drop durability was a copper-organic solderability preservative (Cu-OSP) substrate having a pad thereon. Wettability was measured by coating flux on a polished copper-plate and increasing a reflow belt speed by twice. To analyze the thermal cyclic characteristics, maintaining the solder ball at a temperature of about −45° C. for about 30 minutes, sharply raising the temperature to about 125° C., and maintaining the solder ball at the temperature of about 125° C. for about 30 minutes were performed during one cycle, and the number of cycles were counted until initial destruction occurred. The drop durability was measured according to the JEDEC standard (JESD22-B104). Specifically, an impulse of about 900G was applied to a package to which the solder ball was bonded so that the number of times the impulse was applied was counted until each of initial destruction and final destruction occurred. Analysis of wettability was made using a Rhesca Meniscus Tester (Solder Checker Model SAT-5000).

Tables 1 and 2 show variations in the characteristics of the tin-based solder ball when the silver content of the tin-based solder ball varied.

Table 1 shows a case in which the silver content of a solder ball formed of an Ag—Cu—Sn alloy varied within a range of about 0.3 to 3 wt. %. In this case, the solder ball contained about 0.8 wt. % copper and balance of tin and other unavoidable impurities.

Table 2 shows a case in which the silver content of a solder ball formed of an Ag—Cu—Ni—Bi—Sn alloy varied. In this case, the solder ball contained about 0.8 wt. % copper, 0.05 wt. % nickel, 0.2 wt. % bismuth, and balance of tin and other unavoidable impurities.

Referring to Tables 1 and 2, as the content of silver increased, the number of thermal cycles tended to increase. However, drop durability tended to decrease in both cases of initial destruction and final destruction. Wettability was not greatly changed. Also, as compared with the case (refer to Table 1) in which nickel and bismuth were not contained, in the case (refer to Table 2) in which both nickel and bismuth were contained, each of the number of thermal cycles and drop durability increased. In consideration of contrary tendencies in the number of thermal cycles and drop durability, silver may be contained in the solder ball at a content of about 2 to 2.5 wt. %.

TABLE 1
Ag(x wt %)—Cu(0.8 wt %)—Sn

| | | Drop | Drop | |
|---|---|---|---|---|
| | Thermal | durability | durability | |
| | cycle | (number of | (number of | |
| | (number of | initial | final | |
| Silver(x) | cycles) | destructions) | destructions) | Wettability |
| 0.3 | 900 | 17 | 93 | 0.6 |
| 1 | 1100 | 18 | 91 | 0.6 |
| 2 | 1200 | 18 | 90 | 0.6 |
| 2.5 | 1600 | 15 | 83 | 0.6 |
| 3 | 1500 | 11 | 78 | 0.6 |

TABLE 2
Ag(x wt %)—Cu(0.8 wt %)—Ni(0.05 wt %)—Bi(0.2 wt %)—Sn

| | | Drop | Drop | |
|---|---|---|---|---|
| | Thermal | durability | durability | |
| | cycle | (number of | (number of | |
| | (number of | initial | final | |
| Silver(x) | cycles) | destructions) | destructions) | Wettability |
| 0.3 | 1700 | 25 | 118 | 0.55 |
| 1 | 1800 | 23 | 111 | 0.55 |
| 2 | 2500 | 23 | 115 | 0.6 |
| 2.5 | 3200 | 22 | 108 | 0.6 |
| 3 | 3400 | 16 | 93 | 0.6 |

Tables 3 and 4 show variations in the characteristics of a tin-based solder ball when the copper content of the tin-based solder ball varied.

Table 3 shows a case in which the copper content of a solder ball formed of an Ag—Cu—Sn alloy varied within a range of about 0.4 to 1 wt. %. In this case, the solder ball contained 2.5 wt. % silver and balance of tin and other unavoidable impurities.

Table 4 shows a case in which the copper content of a tin-based solder ball formed of an Ag—Cu—Ni—Bi—Sn alloy varied. In this case, the tin-based solder ball contained about 2.5 wt. % silver, about 0.05 wt. % nickel, about 0.2 wt. % bismuth, and balance of tin and other unavoidable impurities.

Referring to FIGS. 3 and 4, the number of thermal cycles exhibited a maximum value when copper was contained at a content of about 0.8 wt. %, and tended to drop when the copper content increased or decreased from about 0.8 wt. %. Drop durability did not greatly vary according to the copper content in both the cases of the initial destruction and final destruction. Wettability was not largely changed. Also, as compared with the case (refer to Table 3) in which nickel and bismuth were not contained, in the case (refer to Table 4) in which nickel and bismuth were contained, each of the number of thermal cycles and drop durability increased. In consideration of tendencies in the number of thermal cycles and drop durability, copper may be contained in the tin-based solder ball at a content of about 0.8 wt. %.

TABLE 3
Ag(2.5 wt %)—Cu(y wt %)—Sn

| | | Drop | Drop | |
|---|---|---|---|---|
| | Thermal | durability | durability | |
| | cycle | (number of | (number of | |
| Copper | (number of | initial | final | |
| (y) | cycles) | destruction) | destructions) | Wettability |
| 0.4 | 1400 | 16 | 85 | 0.6 |
| 0.5 | 1300 | 15 | 86 | 0.6 |
| 0.8 | 1600 | 15 | 83 | 0.6 |
| 1 | 1400 | 14 | 85 | 0.6 |

TABLE 4
Ag(2.5 wt %)—Cu(y wt %)—Ni(0.05 wt %)—Bi(0.2 wt %)—Sn

| | | | Drop | |
|---|---|---|---|---|
| | Thermal | Drop durability | durability | |
| | cycle | (number of | (number of | |
| Copper | (number of | initial | final | |
| (y) | cycles) | destructions) | destructions) | Wettability |
| 0.4 | 3000 | 20 | 103 | 0.55 |
| 0.5 | 3000 | 20 | 105 | 0.55 |
| 0.8 | 3200 | 22 | 108 | 0.6 |
| 1 | 2800 | 20 | 104 | 0.6 |

Table 5 shows variations in the characteristics of a tin-based solder ball when the bismuth content of a tin-based solder ball varied.

Table 5 shows a case where the bismuth content of a solder ball formed of an Ag—Cu—Ni—Bi—Sn alloy varied within a range of about 0 to 1 wt. %. In this case, the solder ball contained about 2.5 wt. % silver, about 0.8 wt. % copper, about 0.05 wt. % nickel, and balance of tin and other unavoidable impurities.

Referring to Table 5, the number of thermal cycles exhibited a maximum value when bismuth was contained at a content of about 0.2 wt. %, and tended to drop when the copper content increased or decreased from about 0.2 wt. %. Similarly, in both the cases of the initial destruction and final destruction, drop durability exhibited a maximum value when bismuth was contained at a content of about 0.2 wt. %, and tended to drop when the copper content increased or decreased from about 0.2 wt. %. Wettability was not largely changed. In consideration of tendencies in the number of thermal cycles and drop durability, bismuth may be contained in the tin-based solder ball at a content of about 0.2 wt. %.

TABLE 5
Ag(2.5 wt %)—Cu(0.8 wt %)—Ni(0.05 wt %)—Bi(z wt %)—Sn

| | | Drop | Drop | |
|---|---|---|---|---|
| | Thermal | durability | durability | |
| | cycle | (number of | (number of | |
| Bismuth | (number of | initial | final | |
| (z) | cycles) | destructions) | destructions) | Wettability |
| 0 | 1700 | 19 | 98 | 0.6 |
| 0.05 | 2200 | 18 | 101 | 0.6 |
| 0.1 | 2600 | 20 | 103 | 0.6 |
| 0.2 | 3200 | 22 | 108 | 0.6 |
| 0.3 | 2400 | 16 | 97 | 0.6 |
| 0.4 | 2100 | 17 | 95 | 0.6 |
| 0.5 | 2000 | 19 | 93 | 0.6 |
| 1.0 | 1800 | 16 | 90 | 0.6 |

Table 6 shows variations in the characteristics of a tin-based solder ball containing nickel and bismuth. In Table 6, a reference alloy was an Ag(2.5 wt %)-Cu(0.8 wt %)-Sn alloy, and about 0.05 wt. % nickel and about 0.2 wt. % bismuth were further added to the reference alloy. When the reference alloy further contained nickel, all examined characteristics were improved. That is, the number of thermal cycles increased by as much as about 6%, the number of initial destructions for examining drop durability increased by as much as about 26%, and the number of final destructions for examining drop durability increased by as much as about 18%. Also, when the reference alloy further included both nickel and bismuth, all examined characteristics were further improved. That is, the number of thermal cycles increased by as much as about 100%, the number of initial destructions for examining drop durability increased by as much as about 46%, and the number of final destructions for examining drop durability increased by as much as about 30%.

TABLE 6

| | | Drop | Drop | |
|---|---|---|---|---|
| | Thermal | durability | durability | |
| | cycle | (number of | (number of | |
| | (number of | initial | final | |
| Division | cycles) | destructions) | destructions) | Wettability |
| Reference | 1600 | 15 | 83 | 0.6 |
| alloy | | | | |
| Reference | 1700 | 19 | 98 | 0.6 |
| alloy + Ni | (6%- | (26%- | (18%- | (no increase) |
| | increase) | increase) | increase) | |
| Reference | 3200 | 22 | 108 | 0.6 |
| alloy + Ni + Bi | (100%- | (46%- | (30%- | (no increase) |
| | increase) | increase) | increase) | |

Table 7 shows a case in which a tin-based solder ball formed of an Ag—Cu—Ni—Bi—Sn alloy further contained phosphorus. In this case, the tin-based solder ball contained about 2.5 wt. % silver, about 0.8 wt. % copper, about 0.05 wt. % nickel, about 0.2 wt. % bismuth, and balance of tin and other unavoidable impurities.

Referring to Table 7, when phosphorus was contained at a content of about 0.005 wt. % (50 ppm), all characteristics were degraded. Specifically, the number of thermal cycles was reduced by as much as about 50%, the number of initial destructions for examining drop durability was reduced by as much as about 45%, the number of final destructions for examining drop durability was reduced by as much as about 18%, and wettability was reduced by as much as about 45%. Accordingly, it can be clearly seen that limiting the content of phosphorus in solder balls to an extremely low extent may be required. Therefore, the tin-based solder ball 10 according to the present invention may not contain phosphorus or contain phosphorus within the content range of unavoidable impurities.

TABLE 7
Ag(2.5 wt %)—Cu(0.8 wt %)—Ni(0.05 wt %)—Bi(0.2
wt %)—P(q wt %)—Sn

| | | Drop | Drop | |
|---|---|---|---|---|
| | Thermal | durability | durability | |
| | cycle | (number of | (number of | |
| Phosphorus | (number of | initial | final | |
| (q) | cycles) | destructions) | destructions) | Wettability |
| 0 | 3200 | 22 | 108 | 0.6 |
| 0.005 | 1600 | 12 | 89 | 0.33 |
| | (50%- | (45%- | (18%- | (45%- |
| | reduction) | reduction) | reduction) | reduction) |

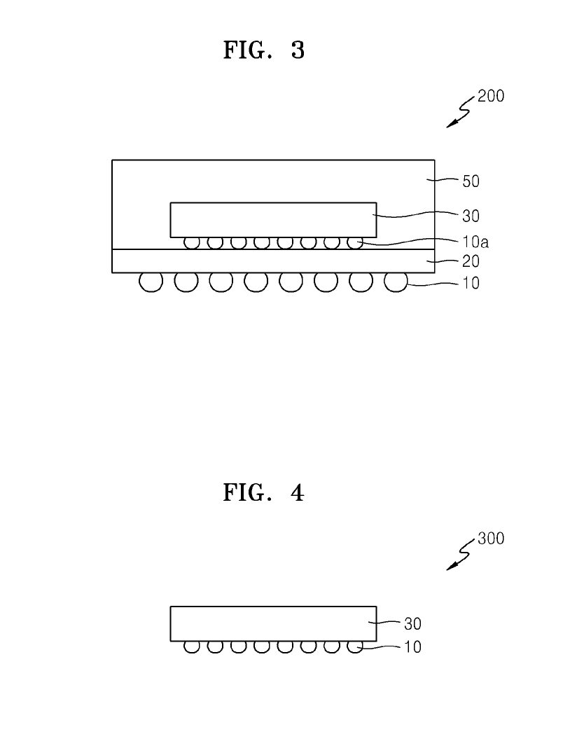

FIGS. 2 through 4 are schematic views of semiconductor packages 100, 200, and 300 including tin-based solder balls 10 according to exemplary embodiments of the present invention.

Referring to FIG. 2, the semiconductor package 100 may include the tin-based solder balls 10, which are the same as described above according to the present invention. The semiconductor package 100 may include a printed circuit board (PCB) 20, a semiconductor chip 30 disposed on the PCB 20, bonding wires 40 configured to electrically connect the semiconductor chip 30 and the PCB 20, and a sealant 50 configured to seal the semiconductor chip 30 and the bonding wires 40. The tin-based solder balls 10 may be adhered to a bottom surface of the PCB 20 and electrically connected to the semiconductor chip 30 through the PCB 20. Here, although FIG. 2 illustrates that the semiconductor package 100 includes one semiconductor chip 30, the semiconductor package 100 according to another embodiment may further include a plurality of semiconductor chips.

Referring to FIG. 3, the semiconductor package 200 may include the tin-based solder balls 10 that are the same as described above according to the present invention. The semiconductor package 100 may include a PCB 20, a semiconductor chip 30 disposed on the PCB 20, inner solder balls 10a configured to electrically connect the semiconductor chips 30 with the PCB 20, and a sealant 50 configured to seal the semiconductor chip 30. The tin-based solder balls 10 may be adhered to a bottom surface of the PCB 20 and electrically connected to the semiconductor chip 30 through the PCB 20. The inner solder balls 10a may contain materials at the same contents as those of the tin-based solder balls 10. The inner solder balls 10a may have a smaller size than the tin-based solder balls 10. Although FIG. 3 illustrates that the semiconductor package 200 includes one semiconductor chip 30, the semiconductor package 200 according to another embodiment may further include a plurality of semiconductor chips.

Referring to FIG. 4, the semiconductor package 300 may include tin-based solder balls 10 that are the same as described above according to the present invention. The semiconductor package 300 may include a semiconductor chip 30 and the tin-based solder balls 10, which may be adhered to a bottom surface of the semiconductor chip 30 and electrically connected to the semiconductor chip 30. The semiconductor chip 30 may be a system-on-chip (SOC) or a system-in-package (SIP). Although FIG. 4 illustrates that the semiconductor package 300 includes one semiconductor chip 30, the semiconductor package 300 according to another embodiment may include a plurality of semiconductor packages.

Although the present specification describes tin-based solder balls, the present invention may be applied to bonding wires. That is, a bonding wire according to the present disclosure may contain about 0.3 to 3.0 wt. % silver; about 0.4 to 0.8 wt. % copper; about 0.01% to 0.09 wt. % nickel; about 0.1 to 0.5 wt. % bismuth, and balance of tin and other unavoidable impurities.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A tin(Sn)-based solder ball comprising:
about 0.3 to 3.0 wt. % silver (Ag);
about 0.4 to 0.8 wt. % copper (Cu);
about 0.01 to 0.09 wt. % nickel (Ni);
about 0.1% to 0.5 wt. % bismuth (Bi); and
balance of tin (Sn) and unavoidable impurities.

2. The tin-based solder ball of claim 1, wherein bismuth is contained at a content of about 0.1 to 0.3 wt. %.

3. The tin-based solder ball of claim 1, wherein bismuth is contained at a content of about 0.2(±0.02) wt. %.

4. The tin-based solder ball of claim 1, wherein nickel is contained at a content of about 0.05(±0.01) wt. %.

5. The tin-based solder ball of claim 1, wherein silver is contained at a content of about 2.5 wt. %, copper is contained at a content of about 0.8 wt. %, nickel is contained at a content of about 0.05 wt. %, and bismuth is contained at a content of about 0.2 wt. %.

6. A tin(Sn)-based solder ball comprising silver (Ag), copper (Cu), nickel (Ni), bismuth (Bi), and balance of tin (Sn) and unavoidable impurities, the tin-based solder ball from which phosphorus (P) is removed.

7. A semiconductor package comprising a tin(Sn)-based solder ball,
wherein the tin-based solder ball comprises:
about 0.3 to 3.0 wt. % silver (Ag);
about 0.4 to 0.8 wt. % copper (Cu);
about 0.01 to 0.09 wt. % nickel (Ni);
about 0.1% to 0.5 wt. % bismuth (Bi); and
balance of tin (Sn) and unavoidable impurities
